(19) United States
(12) Patent Application Publication
(10) Pub. No.: US 2013/0256681 A1
(43) Pub. Date: Oct. 3, 2013

(54) GROUP III NITRIDE-BASED HIGH ELECTRON MOBILITY TRANSISTOR

(71) Applicants: Winston WANG, Tao Yuan Shien (TW); Willie Huang, Tao Yuan Shien (TW); Ivan Huang, Tao Yuan Shien (TW)

(72) Inventors: Winston WANG, Tao Yuan Shien (TW); Willie Huang, Tao Yuan Shien (TW); Ivan Huang, Tao Yuan Shien (TW)

(73) Assignee: WIN Semiconductors Corp., Tao Yuan Shien (TW)

(21) Appl. No.: 13/437,091

(22) Filed: Apr. 2, 2012

(51) Int. Cl. H01L 29/778; H01L 29/16

(52) U.S. Cl. 257/76; 257/77; 257/E29.089; 257/E29.082; 257/E29.246

(57) ABSTRACT

A group III nitride-based high electron mobility transistor (HEMT) is disclosed. The group III nitride-based high electron mobility transistor (HEMT) comprises sequentially a substrate, a GaN buffer layer, a GaN channel layer, a AlN spacer layer, a barrier layer, a GaN cap layer, and a delta doped layer inserted between the AlN spacer layer and the barrier layer. The HEMT structure of the present invention can improve the electron mobility and concentration of the two-dimensional electron gas, while keeping a low contact resistance.

### FIELD OF THE INVENTION

The present invention relates to a high electron mobility transistor (HEMT), in particular to a group III nitride-based HEMT.

### BACKGROUND OF THE INVENTION

A group III nitride-based high electron mobility transistor (HEMT) has a relatively higher breakdown voltage and switching speed comparing with a GaAs based HEMT. It has been an important device in the high power and high frequency applications such as in integrated wireless circuits.

A typical GaN HEMT structure is as shown in FIG. 1, which comprises a GaN buffer layer 103, and an AlₓGa₁₋ₓN layer 105 adjacent to the GaN buffer layer 103. The GaN buffer layer 103 is grown on a substrate 101 made preferably of a material selected from the group consisting of SiC, Si, and sapphire. Between the GaN buffer layer and the substrate, a nucleation layer 102 can be included to reduce the lattice mismatch between the two layers. The AlₓGa₁₋ₓN layer 105 will create polarization charges at the interface between the GaN buffer layer 103 and the AlₓGa₁₋ₓN layer 105 due to the strain induced piezoelectric polarization and the spontaneous polarization of the AlₓGa₁₋ₓN layer. The polarization charges then induces a two-dimensional electron gas (2DEG) 104 at the interface and forms a conducting channel. The typical Al content, x, of the AlₓGa₁₋ₓN layer 105 is between 0.1 and 0.4. Since the strain in the AlₓGa₁₋ₓN layer increases with the Al content x, a higher density of polarization charges and hence more 2DEG will be formed at the interface channel when using a high-Al-content layer. However, increasing the Al content in the AlₓGa₁₋ₓN layer will inevitably increase the composition fluctuation at the interface, which will enhance the carrier scatterings in the channel and hence degrade the electron mobility of the 2DEG. The contact resistance will also be increased by increasing the Al content. Therefore, it is necessary to provide a GaN HEMT structure, which can improve both mobility and concentration of the 2DEG while keeping a low contact resistance.

### SUMMARY OF THE INVENTION

The main object of the present invention is to provide a group III nitride-based high electron mobility transistor (HEMT), in which a delta-doped layer is inserted between the spacer layer and the barrier layer, so that the contact resistance can be reduced, and the two-dimensional electron gas (2DEG) can be enhanced.

To reach the objects stated above, the present invention provides a group III nitride-based HEMT, which comprises sequentially a substrate, a GaN buffer layer, a GaN channel layer, an AlN spacer layer, a delta-doped layer, a barrier layer, and a GaN cap layer.

In implementation, the substrate mentioned above is made preferably of a material selected from the group consisting of SiC, Si, GaN, and sapphire. The barrier layer mentioned above is made preferably of AlₓGa₁₋ₓN with a preferable Al content in the range of 0.1≦x≦0.4, or In_{y}Al_{1-y}N with a preferable In content in the range of 0.17≦y≦0.29.

In implementation, the HEMT structure of the present invention may further includes multiple uniformly n-type doped layer and delta-doped layer alternatively inserted between the delta-doped layer and the barrier layer mentioned above. Considering a delta doped layer and a uniformly n-type doped layer as a pair, then the HEMT structure may includes in total N pairs of a delta-doped layer and a uniformly n-type doped layer with a preferable number of pairs in the range of 1≦N≦5.

In implementation, the preferable dopant of the delta-doped layer mentioned above is Si with a preferable doping concentration of 10¹⁷˜10¹⁹ cm⁻³ and a preferable thickness of 3 to 20 Å.

In implementation, the uniformly n-type doped layer mentioned above is made preferably of AlₓGa₁₋ₓN layer with an Al content preferably in the range of 0.1≦x≦0.4, or In_{y}Al_{1-y}N with an In content preferably in the range of 0.17≦y≦0.29. The preferable dopant of the uniformly n-type doped layers mentioned above is Si with a preferable doping concentration of 10¹⁷˜10¹⁸ cm⁻³ and a preferable thickness of 3 to 20 Å.

For further understanding the characteristics and effects of the present invention, some preferred embodiments referred to drawings are in detail described as follows

### BRIEF DESCRIPTION OF DRAWINGS

FIG. 1 is a schematic showing the cross-sectional views of the structure of HEMT devices of prior art.

FIGS. 2A˜2E are schematics showing the cross-sectional views of the structure of HEMT devices according to the present invention.

FIGS. 3A and 3B are graphs illustrating the variation of the drain-to-source current (I_{ds}) versus the voltage (V_{ds}) with different Si doping concentration and different thickness of the Si delta-doped layer, when the gate voltage V_{g}=0V.

FIG. 4 is a graph illustrating the simulation results of the HEMT structure with and without the delta doped layer.

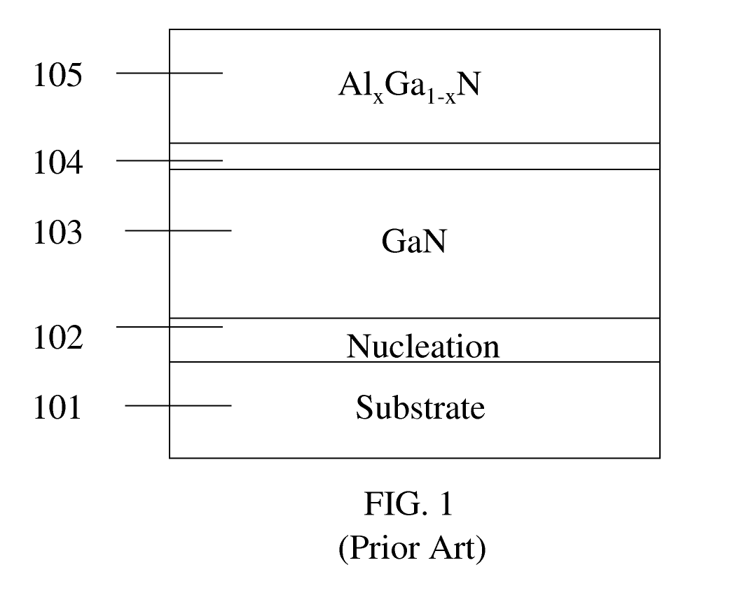

### DETAILED DESCRIPTIONS OF PREFERRED EMBODIMENTS

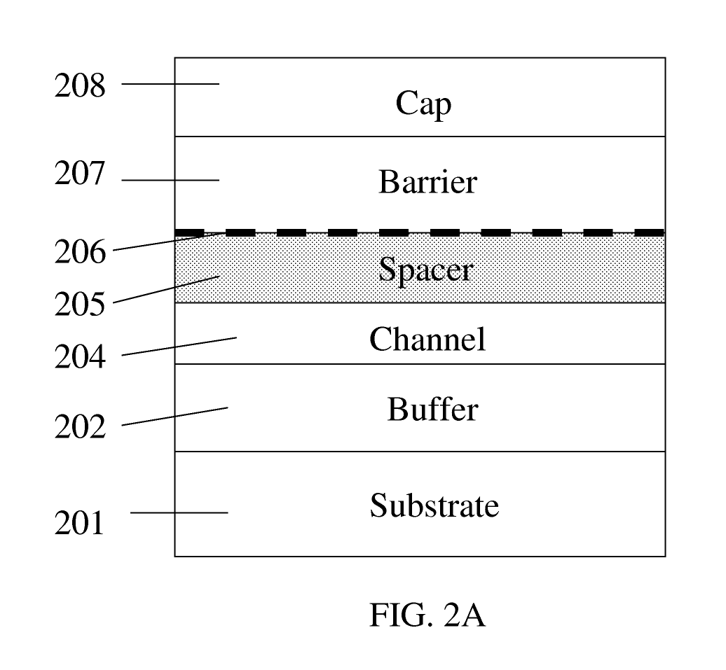

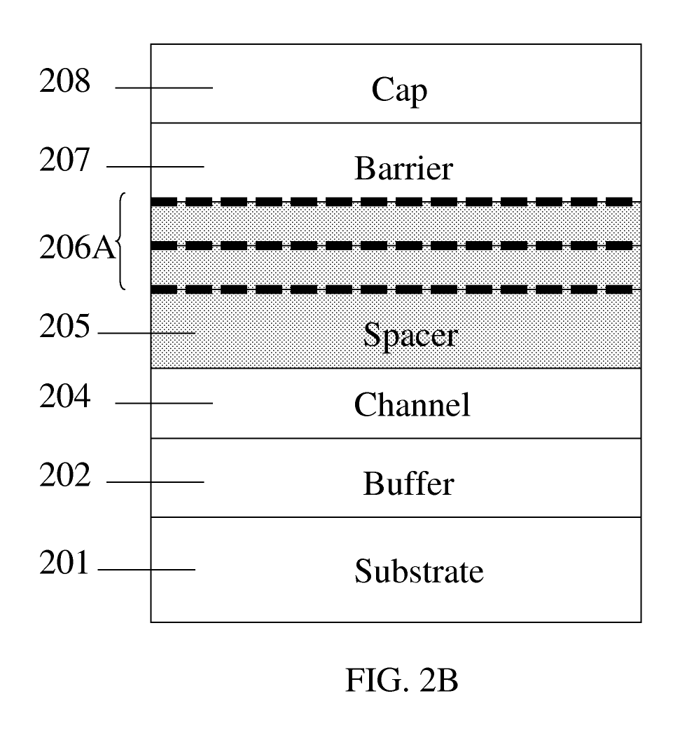

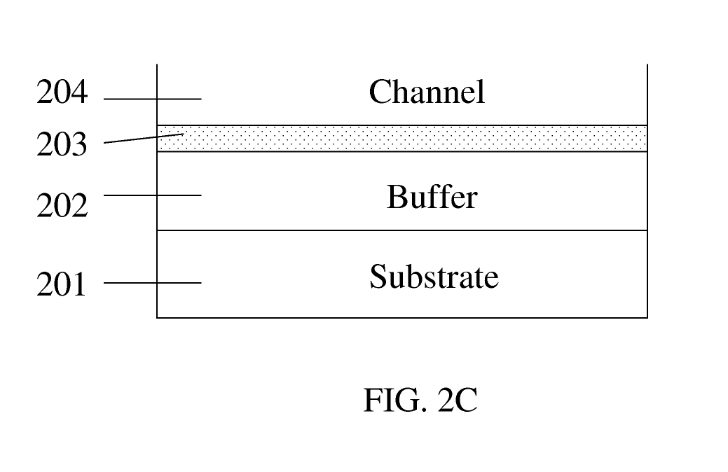

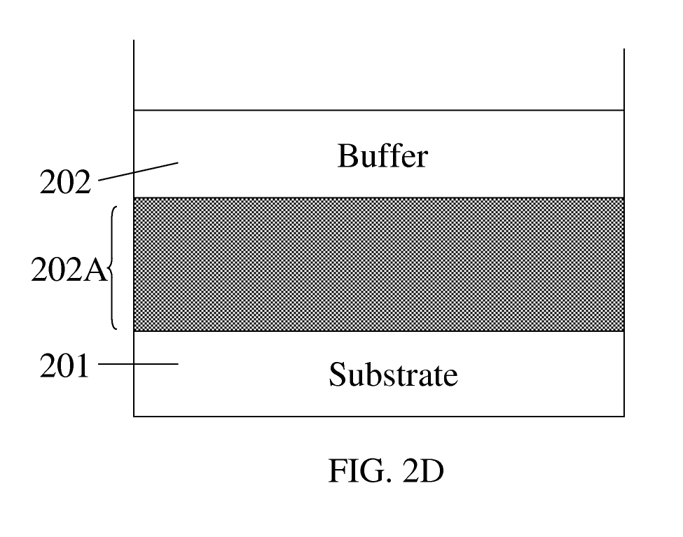

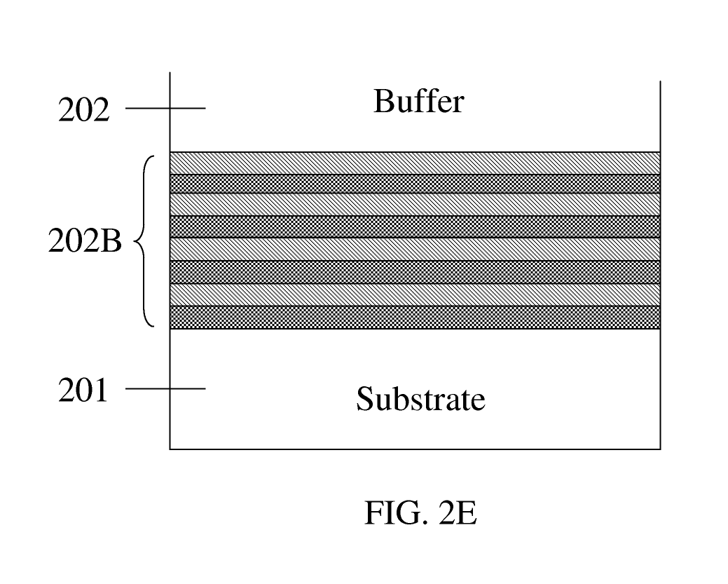

FIG. 2A is a schematic showing the cross-sectional view of the group III nitride based HEMT structure according to the present invention, which comprises a substrate 201, a GaN buffer layer 202, a GaN channel layer 204, an AlN spacer layer 205, a delta-doped layer 206, a barrier layer 207, and a GaN cap layer 208.

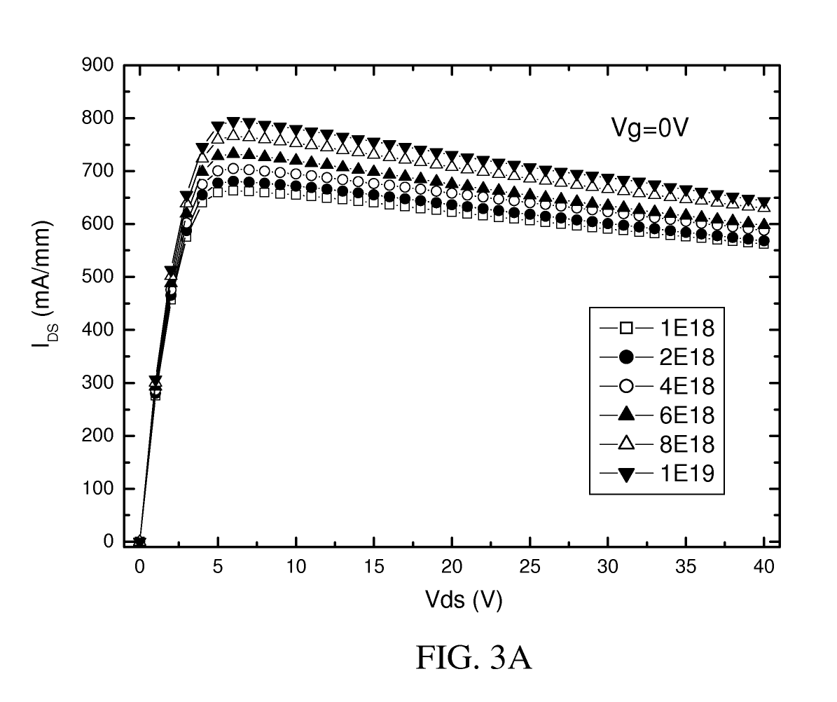

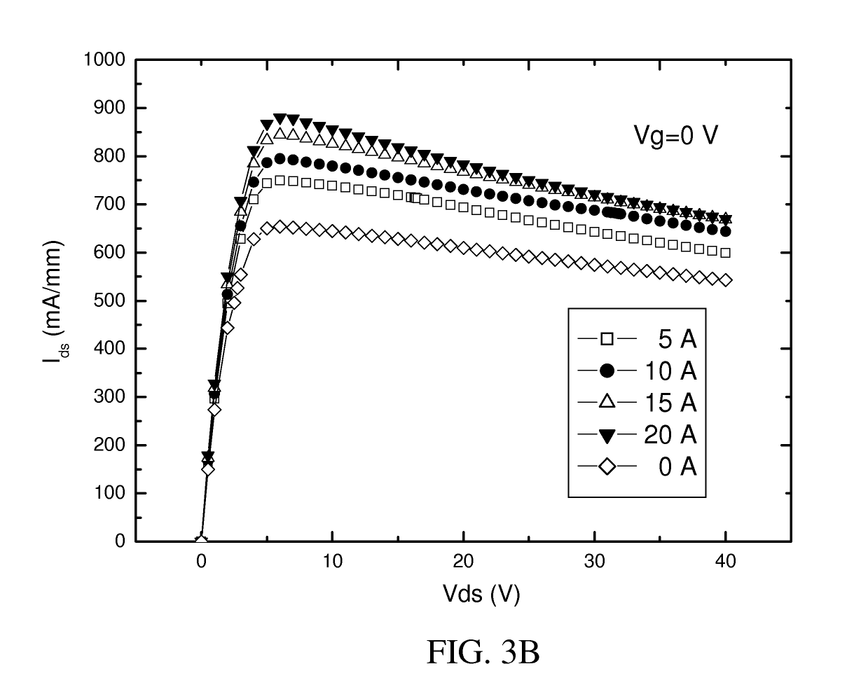

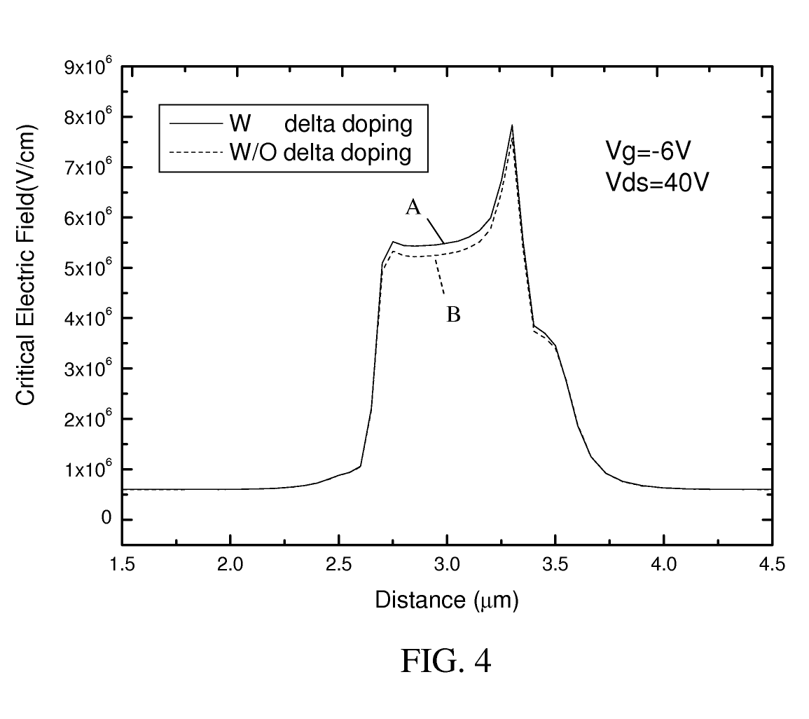

In the present structure, the substrate 201 is usually made of semi-insulating material preferably selected from the group consisting of SiC, Si, GaN, and sapphire. The group-III nitride epilayers formed on the substrate can be grown either by molecular beam epitaxy (MBE) or by metal-organic chemical vapor deposition (MOCVD). Before the growth of GaN buffer layer, a nucleation layer, preferably an AlN layer or a GaN layer, can be grown on the substrate 201 in order to reduce the lattice mismatch between the substrate and GaN. The unintentionally doped GaN buffer layer 202 is then formed on the nucleation layer with a thickness preferably ranging from 1 μm to 4 μm. The GaN channel layer 204 formed by an unintentionally doped GaN layer with a thickness in the range of 15-30 nm is then grown on the GaN buffer layer 202. On the GaN channel layer 204, an AlN spacer layer 205 followed by a delta-doped layer 206 and a barrier layer 207 are formed. The HEMT structure is finally completed by covering on top of the structure an intentionally doped or an n-type doped GaN capping layer 208 with a doping concentration till 1×10¹⁸ cm⁻³. The delta-doped layer 206 is formed preferably by depositing one monolayer of Si atoms on the AlN spacer layer, corresponding to a thickness of about 3˜20 Å. The Si doping concentration is preferably in the range of 10¹⁷-10¹⁹ cm⁻³. The barrier layer 207 formed above the AlN spacer layer 205 and the delta-doped layer 206 is made of AlₓGa₁₋ₓN with an Al content preferably in the range of 0.1≦x≦0.4, or In_{y}Al_{1-y}N with an In content preferably in the range of 0.17≦y≦0.29. FIGS. 3A and 3B show a graph illustrating the variation of the drain-to-source current (I_{ds}) versus the voltage (V_{ds}) with different Si doping concentration and different thickness of the Si delta-doped layer, when the gate voltage V_{g}=0V. The figures show that for the same V_{ds}, the I_{ds} is higher by increasing the Si doping concentration or the thickness of the Si delta-doped layer, which means that the insertion of the Si delta-doped layer will lower the on resistance. FIG. 4 shows a graph illustrating the simulation results of the critical electric field of an HEMT structure with (line A) and without (line B) the delta doped layer 206 operating at a gate voltage of V_{g}=−6V and a drain to source voltage of V_{ds}=40V. The small increase of critical electric field in the gate region is observed in the case of the HEMT structure with the delta doped layer 206 but it could be relieved during device fabrication like field-plate design.

FIG. 2B is a schematic showing the cross-sectional view of another structure of the group III nitride based HEMT according to the present invention, in which a modulation doped layer 206A is inserted between the AlN spacer layer 205 and the barrier layer 207. The modulation doped layer 206A consists of alternating layers comprising at least one pair of delta doped layer and uniformly n-type doped layer. The preferable dopant of the delta-doped layer is Si with a preferable concentration in the range of 10¹⁷-10¹⁹ cm⁻³ and a preferable thickness in the range of 3˜20 Å. The preferable material for the uniformly n-type doped layer is AlₓGa₁₋ₓN with an Al content, x, preferably in the range of 0.1≦x≦0.4, or In_{y}Al_{1-y}N with an In content, y, preferably in the range of 0.17≦y≦0.29. The preferable dopant of the uniformly n-type doped layer is Si with a preferable concentration in the range of 10¹⁷-10¹⁸ cm⁻³ and a preferable thickness in the range of 3-20 Å. The modulation doped layer may consist of N pairs of delta doped layer and uniformly n-type doped layer with the preferable range of 1≦N≦5.

The HEMT structure of the present invention can further include a thin back barrier layer 203 between the buffer layer 202 and the channel layer 204, as shown in FIG. 2C. The preferable material for the back barrier layer 203 is InₓGa₁₋ₓN with a low In content 0.1≦x<0.2. The polarization-induced field in the back barrier layer 203 can raise the conduction band of the GaN buffer and enhance the confinement of the 2DEG in the conducting channel.

FIG. 2D and 2E are schematics showing the cross sectional view of the HEMT device according to the present invention with different buffer layer structure. As shown in FIG. 2D, the buffer layer 202 in the HEMT structure of the present invention can further include a graded AlₓGa₁₋ₓN layer 202A inserted between the GaN buffer layer 202 and the substrate 201 with an Al content, x, graded from 1 to 0.05. Another structure of the buffer layer 202, as shown in FIG. 2E, further includes a GaN/AlGaN supperlattice 202B inserted between the GaN buffer layer 202 and the substrate 201.

To sum up, the present invention indeed can get its anticipatory object that is to provide a HEMT device, in which a delta-doped layer is inserted between the spacer layer and the barrier layer, so that the device can have a lower contact resistance, and the 2DEG can be enhanced and hence the device performance can be improved.

The description referred to the drawings stated above is only for the preferred embodiments of the present invention. Many equivalent partial variations and modifications can still be made by those skilled at the field related with the present invention and do not depart from the spirits of the present invention, so they should be regarded to fall into the scope defined by the appended claims.

1. A group III nitride-based high electron mobility transistor (HEMT) comprising sequentially:
a substrate;
a GaN buffer layer;
a GaN channel layer;
a AlN spacer layer;
a delta-doped layer;
a barrier layer; and
a GaN cap layer.

2. The group III nitride-based HEMT according to claim 1, wherein said substrate is made from a material selected from the group consisting of SiC, Si, GaN, and sapphire.

3. The group III nitride-based HEMT according to claim 1, wherein said barrier layer is an AlₓGa₁₋ₓN layer with 0.1≦x≦0.4.

4. The group III nitride-based HEMT according to claim 1, wherein said barrier layer is an In_{y}Al_{1-y}N layer with 0.17≦y≦0.29.

5. The group III nitride-based HEMT according to claim 1, wherein the dopant of said delta-doped layer is Si.

6. The group III nitride-based HEMT according to claim 5, wherein the Si doping concentration is 10¹⁷˜10¹⁹cm⁻³.

7. The group III nitride-based HEMT according to claim 5, wherein the thickness of said Si delta-doped layer is 3 to 20 Å.

8. The group III nitride-based HEMT according to claim 1, further comprising a uniformly n-type doped layer inserted between said delta-doped layer and said barrier layer.

9. The group III nitride-based HEMT according to claim 8, wherein said uniformly n-type doped layer is an AlₓGa₁₋ₓN layer with 0.1≦x≦0.4.

10. The group III nitride-based HEMT according to claim 8, wherein said uniformly n-type doped layer is an In_{y}Al_{1-y}N layer with 0.17≦y≦0.29.

11. The group III nitride-based HEMT according to claim 8, wherein the dopant of said uniformly n-type doped layer is Si.

12. The group III nitride-based HEMT according to claim 11, wherein the Si doping concentration is 10¹⁷˜10¹⁸ cm⁻³.

13. The group III nitride-based HEMT according to claim 8, wherein the thickness of said uniformly n-type doped layer is 3 to 20 Å.

14. The group III nitride-based HEMT according to claim 8, further comprising multiple delta-doped layers and uniformly n-type doped layers alternatively inserted between said uniformly n-type doped layer and said barrier layer.

15. The group III nitride-based HEMT according to claim 14, wherein a delta-doped layer and a uniformly n-type doped layer are considered as a pair, and N pairs of delta-doped layer and uniformly n-type Si-doped layer are inserted between said uniformly n-type doped layer and said barrier layer with 1≦N≦4.

16. The group III nitride-based HEMT according to claim 14, wherein the dopant of said delta-doped layer is Si.

17. The group III nitride-based HEMT according to claim 16, wherein the Si doping concentration is 10¹⁷˜10¹⁹ cm⁻³.

18. The group III nitride-based HEMT according to claim 16, wherein the thickness of said Si delta-doped layer is 3 to 20 Å.

19. The group III nitride-based HEMT according to claim 14, wherein said uniformly n-type doped layer is an AlₓGa₁₋ₓN layer with 0.1≦x≦0.4.

20. The group III nitride-based HEMT according to claim 14, wherein said uniformly n-type doped layer is an In_{y}Al_{1-y}N layer with 0.17≦y≦0.29.

21. The group III nitride-based HEMT according to claim 14, wherein the dopant of said uniformly n-type doped layer is Si.

22. The group III nitride-based HEMT according to claim 21, wherein the Si doping concentration is 10¹⁷˜10¹⁸ cm⁻³.

23. The group III nitride-based HEMT according to claim 14, wherein the thickness of said uniformly n-type doped layer is 3 to 20 Å.

24. The group III nitride-based HEMT according to claim 1, further comprising a back barrier layer inserted between said GaN buffer layer and said GaN channel layer.

25. The group III nitride-based HEMT according to claim 24, wherein said back barrier layer is formed of an InₓGa₁₋ₓN layer with 0.1≦x≦0.2.

26. The group III nitride-based HEMT according to claim 1, further comprising a graded AlₓGa₁₋ₓN layer inserted between said GaN buffer layer and said substrate with a Al content, x, degraded from 1 to 0.05.

27. The group III nitride-based HEMT according to claim 1, further comprising a GaN/AlGaN supperlattice inserted between said GaN buffer layer and said substrate.
